(19) United States
(12) Patent Application Publication
(10) Pub. No.: US 2024/0145469 A1
(43) Pub. Date: May 2, 2024

(54) ONE TIME PROGRAMMABLE DEVICE

(71) Applicant: GlobalFoundries U.S. Inc., Malta, NY (US)

(72) Inventors: Santosh SHARMA, Austin, TX (US); Johnatan A. KANTAROVSKY, South Burlington, VT (US)

(21) Appl. No.: 17/974,005

(22) Filed: Oct. 26, 2022

(51) Int. Cl. H01L 27/088; H01L 27/10; H01L 29/20

(52) U.S. Cl. CPC H01L 27/0883; H01L 27/101; H01L 29/2003

(57) ABSTRACT

The present disclosure relates to semiconductor structures and, more particularly, to a depletion mode device with a programmable element used for chip programming and circuit configuration and methods of manufacture and operation. In particular, the structure includes a programmable element on an active layer of semiconductor material, and a depletion mode device comprising a dual gate connected to the programmable element.

### BACKGROUND

The present disclosure relates to semiconductor structures and, more particularly, to a depletion mode device with a programmable element used for chip programming and circuit configuration and methods of manufacture and operation.

Integrated circuits in gallium nitride (GaN) devices currently do not have any mechanism to perform one time programming at a wafer level. In other words, known GaN devices do not allow for circuit tuning, debugging, or circuit configuration at the wafer level. To provide such programming, a companion chip is placed next to the GaN chip and programming is performed via the companion chip in final product assembly. However, this type of configuration does not provide for programming at the wafer level. In addition, circuit trimming in silicon may not be very effective in negating intrinsic process and lifetime variations in GaN device parameters.

### SUMMARY

In an aspect of the disclosure, a structure comprises: a programmable element on an active layer of semiconductor material, and a depletion mode device comprising a dual gate connected to the programmable element.

In an aspect of the disclosure, a structure comprises: at least two depletion mode gate islands; and at least two gate islands interspersed between the at least two depletion mode gate islands.

In an aspect of the disclosure, a method comprises: forming a programmable element on an active layer of a semiconductor material; and forming a depletion mode device comprising a dual gate in contact with the programmable element.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a circuit with a programming element, amongst other features, in accordance with aspects of the present disclosure.

FIG. 2 shows the programming element of FIG. 1, amongst other features, in accordance with aspects of the present disclosure.

FIGS. 3A-3B show a depletion mode structure with a modulation pinch voltage, amongst other features, in accordance with aspects of the present disclosure.

FIGS. 4A-4B show a depletion mode structure with the modulated pinch voltage, amongst other features, in accordance with additional aspects of the present disclosure.

FIGS. 5A-5B show a capacitor structure, amongst other features, in accordance with aspects of the present disclosure.

### DETAILED DESCRIPTION

The present disclosure relates to semiconductor structures and, more particularly, to a depletion mode device with a programmable element used for chip programming and circuit configuration and methods of manufacture and operation. In more specific embodiments, a programmable element may be used as an open circuit for purposes of programming at a wafer level. Accordingly, a depletion mode device may be biased such that a pinch off voltage is programmable. In this way, by combining a biased depletion mode device and the programmable element, a logic signal may be created for chip programming or configuring.

Advantageously, the depletion mode device with a one time programmable element allows for gallium nitride (GaN) integrated circuit tuning at a wafer level. In addition, the depletion mode device does not require any additional mask adder or a dedicated one time programmable device.

The device of the present disclosure may be manufactured in several ways using a number of different tools. In general, though, the methodologies and tools are used to form structures with dimensions in the micrometer and nanometer scale. The methodologies, i.e., technologies, employed to manufacture the device of the present disclosure have been adopted from integrated circuit (IC) technology. For example, the structures are built on wafers and are realized in films of material patterned by photolithographic processes on the top of a wafer. In particular, the fabrication of the device uses three basic building blocks: (i) deposition of thin films of material on a substrate, (ii) applying a patterned mask on top of the films by photolithographic imaging, and (iii) etching the films selectively to the mask.

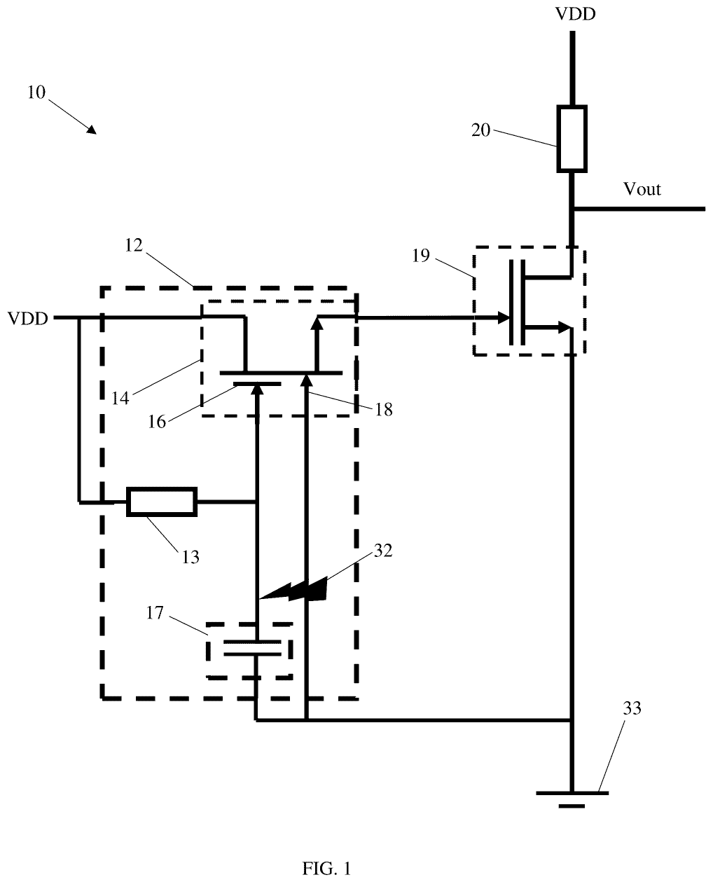

FIG. 1 shows a circuit with a programming element, amongst other features, in accordance with aspects of the present disclosure. In FIG. 1, a circuit 10 includes a programming element 12, a transistor 19 and a load 20. The programmable element 12 may be between the transistor 19 and a voltage power supply Vdd. In embodiments, the transistor 19 may be an enhancement mode device, although this should not be considered a limiting feature of the present disclosure. Further, the load 20 may be a resistor between the voltage power supply Vdd and the transistor 19. In alternative embodiments, the load 20 may be a capacitor, transistor, etc. Also, in FIG. 1, a voltage output Vout may be between the load 20 and the transistor 19.

In FIG. 1, the programming element 12 of the circuit 10 may include a depletion mode device with dual gate 14, a programming pad 32, a resistor 13, and a gate capacitor 17. In specific embodiments, the depletion mode device with dual gate 14 may include a p-doped GaN (pGaN) gate 16 and a depletion mode gate 18. Further, the depletion mode device with dual gate 14 may be between the transistor 19 and the voltage power supply Vdd. The programming pad 32 may be between the gate capacitor 17 and the depletion mode device with dual gate 14. Further, the resistor 13 may be between the voltage power supply Vdd and the pGaN gate 16, and the gate capacitor 17 may be between ground 33 and the pGaN gate 16. In embodiments, the gate capacitor 17 may be a pGaN capacitor and the resistor 13 may be a pGaN resistor; although other embodiments are also contemplated herein.

In the operation of the circuit 10 of FIG. 1, a leakage of the gate capacitor 17 may be increased by orders of magnitude once the gate capacitor 17 is exposed to a programming voltage through the programming pad 32. For example, before the circuit 10 is programmed, the pGaN gate 16, in the depletion mode, may be tied to the voltage power supply Vdd via the resistor 13. In this operational mode, a pinch off voltage of the depletion mode device with dual gate 14 may be close to a value of the voltage power supply Vdd, a gate of the transistor 19 may be close to the value of the voltage power supply Vdd, and the voltage output Vout may be zero volts (i.e., logic “1”).

Further, after the circuit 10 is programmed, the leakage of the gate capacitor 17 may pull the pGaN gate 16 to zero volts. In this operational mode, the magnitude of the pinch off voltage of the depletion mode device with dual gate 14 may be set to below a threshold voltage of the transistor 19, e.g., 1 volt. As 1 volt is below a threshold voltage of the transistor 19, the voltage output Vout may rise up to the value of the voltage power supply Vdd (i.e., logic “0”). In embodiments, the threshold voltage of the transistor 19 may be in a range between 1.5 and 2.0 volts; although embodiments are not limited to this range. Accordingly, the circuit 10 may use a signal transition (i.e., from logic “1” to logic “0”) of the voltage output Vout as a programming technique for tuning analog references, adjusting thresholds, configuring a chip, etc.

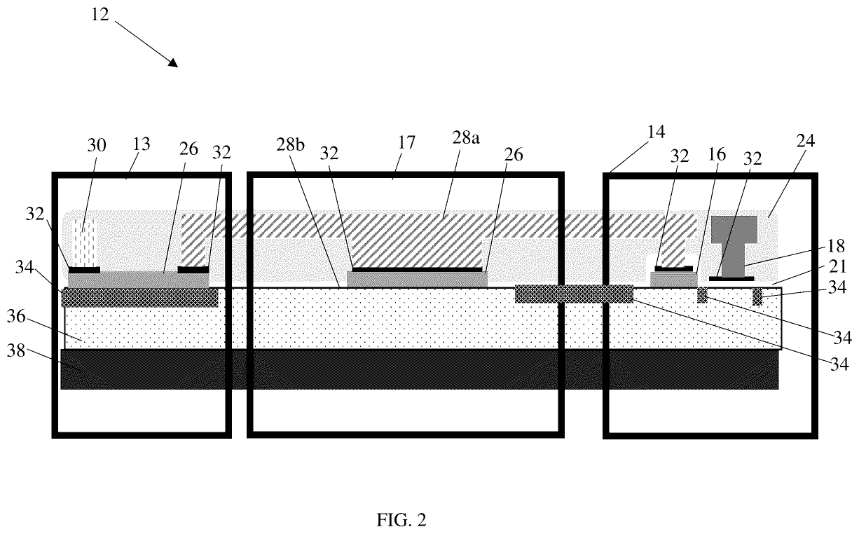

FIG. 2 shows the programming element of FIG. 1, amongst other features, in accordance with aspects of the present disclosure. In FIG. 2, the programming element 12 includes a semiconductor substrate 38 composed of any suitable semiconductor material including, but not limited to, Si, SiGe, SiGeC, SiC, GaAs, InAs, InP, and other III/V or II/VI compound semiconductors. In specific embodiments, the semiconductor substrate 38 may be p-type Si. An active device layer 36 may be formed (e.g., deposited) on the semiconductor substrate 38 using any conventional deposition methods, e.g., CVD or epitaxial growth processes. In embodiments, the active device layer 36 may be composed of GaN and/or AlGaN.

In embodiments, isolation structures 34 may be formed within the active device layer 36 by implanted isolation. A dielectric material 21 may be deposited on the active device layer 36 and the isolation structures 34, after formation of a gate structure 26, by conventional deposition methods, e.g., CVD.

Still referring to FIG. 2, the gate structure 26 comprises GaN material and, more preferably, a pGaN material formed on the active device layer 36. In embodiments, the programming pad 32 may be formed on the gate structure 26. The gate structure 26 and the programming pad 32 may be deposited by a conventional deposition method (e.g., chemical vapor deposition (CVD)), followed by conventional lithography and etching processes. A top plate 28a of a capacitor (gate capacitor 17) may be formed in contact with the programming pad 32. A bottom plate 28b of the capacitor contact may be formed over the active device layer 36.

In FIG. 2, the resistor 13 comprises a resistive contact 30 in contact with the programming pad 32. The depletion mode device with dual gate 14 in FIG. 2 comprises the pGaN gate 16 and the depletion mode gate 18 in contact with the programming pad 32. In embodiments, the pGaN gate 16 may be tied together with the resistor 13, the gate capacitor 17, and the depletion mode device with dual gate 14. The depletion mode gate 18, the top and bottom plates 28a, 28b of the capacitor, and the resistive contact 30 may be formed in a dielectric layer 24 by conventional deposition processes, followed by patterning processes as already described herein.

In an example operation, when the pGaN gate 16 is tied to the value of the voltage power supply Vdd (e.g., 6 volts), the pinch off voltage of the depletion mode device with dual gate 14 may be set to around −6 volts. This is due to a channel of the depletion mode device with dual gate 14 being in a fully enhanced state. In another example operation, when the pGaN gate 16 is tied to 0 volts, the pinch off voltage of the depletion mode device with dual gate 14 may be set to around −1 volt, whose magnitude is below the threshold of the transistor 19 in FIG. 1.

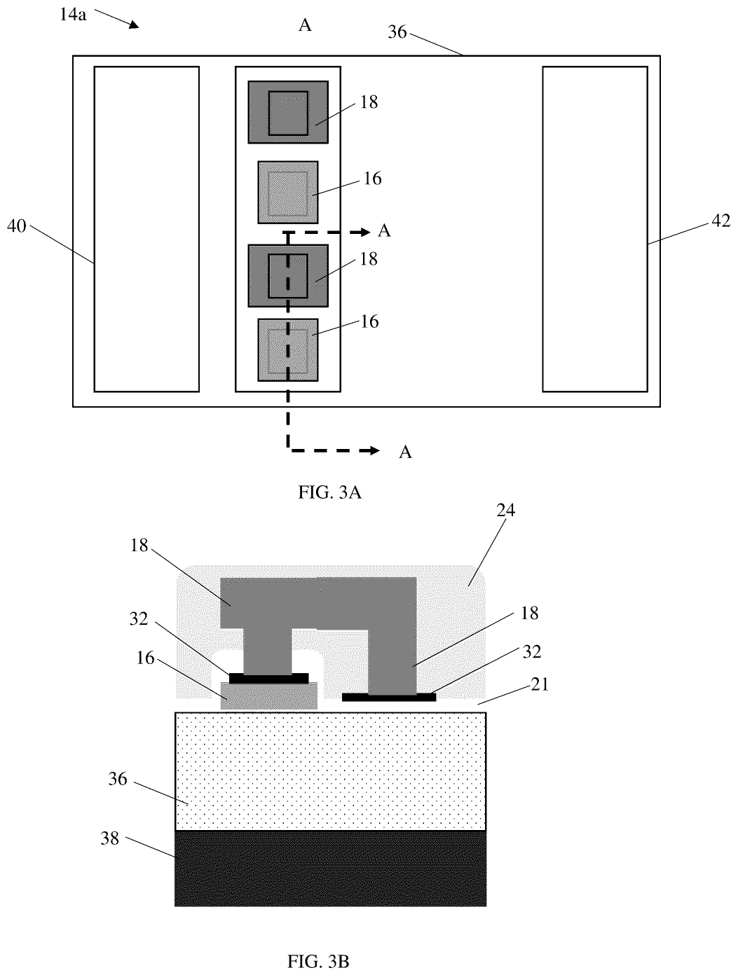

FIGS. 3A and 3B show a layout of a depletion mode structure with a modulation pinch voltage in accordance with additional aspects of the present disclosure. In particular, FIG. 3A shows a top view of the depletion mode device with dual gate 14a and FIG. 3B shows a cross section view of the depletion mode device with dual gate 14a along lines A-A.

In FIGS. 3A and 3B, the depletion mode device with dual gate 14a includes a source 40 and a drain 42. The depletion mode gate 18 (i.e., depletion mode gate islands), along a gate width, is alternating with the pGaN gate 16 (i.e., pGaN islands). Further, each of the pGaN gates 16 (i.e., pGaN islands) act to deplete the 2DEG (e.g., 2 dimensional electron gas) concentration under the depletion mode gate 18 to reduce a pinch off voltage (e.g., modulated pinch off voltage). In embodiments, a ratio of a first width of the pGaN gate 16 to a second width of the depletion mode gate 18 determines a threshold voltage (Vt) in the depletion mode device with dual gate 14a. In further embodiments, instead of the depletion mode gate 18, a field plate may be used for an enhancement mode device.

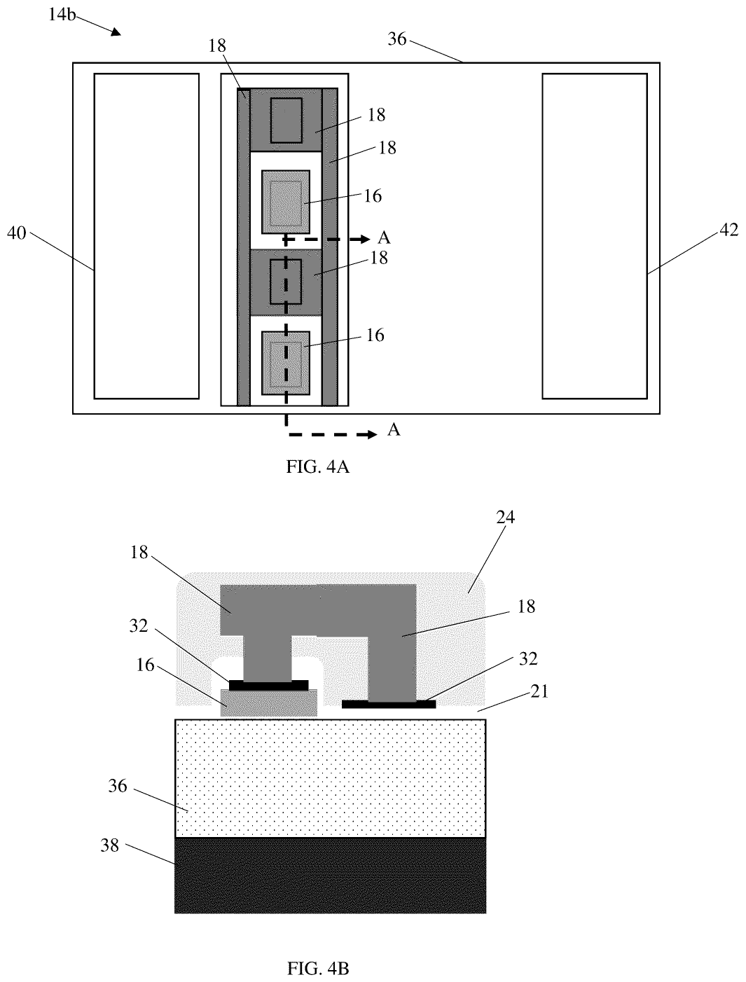

FIGS. 4A-4B show another depletion mode structure with the modulated pinch voltage, amongst other features, in accordance with additional aspects of the present disclosure. FIG. 4A shows a top view of the depletion mode device with dual gate 14b and FIG. 4B shows a cross section view of the depletion mode device with dual gate 14b along lines A-A. In FIGS. 4A and 4B, the pGaN gate 16 (i.e., pGaN islands) is provided within holes of the depletion mode gate 18 (i.e., depletion mode gate islands) along a gate width. In this way, the depletion mode gate 18 surrounds the p GaN gate 16 (i.e., pGaN islands).

In FIGS. 4A and 4B, an electric field may be reduced at an edge of the p GaN gate 16 by the pGaN gate 16 (i.e., pGaN islands) being provided within the holes of the depletion mode gate 18 (i.e., depletion mode gate islands) along the gate width. By reducing the electric field, a threshold voltage (Vt) may be further modulated in comparison to the depletion mode device with the dual gate 14a of FIGS. 3A and 3B. In addition, by reducing the electric field, reliability and performance may be improved in comparison to the depletion mode device with the dual gate 14a of FIGS. 3A and 3B. In further embodiments, the depletion mode gate 18 may be self aligned (e.g., vertically aligned) to the pGaN gate 16. In other embodiments, instead of the depletion mode gate 18, a field plate may be self-aligned to the pGaN gate 16 in an enhancement mode device.

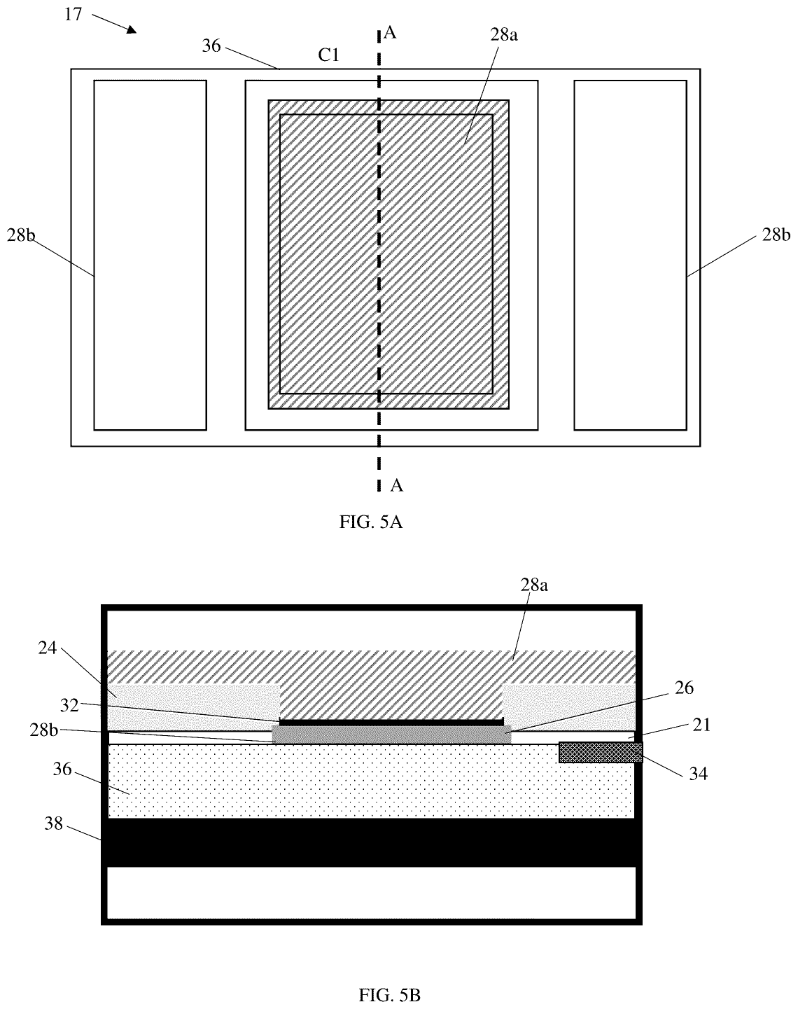

FIGS. 5A and 5B show a capacitor structure, amongst other features, in accordance with additional aspects of the present disclosure. FIG. 5A shows a top view of the gate capacitor 17 and FIG. 5B shows a cross section view of the gate capacitor 17 along lines A-A. In FIGS. 5A and 5B, the gate capacitor 17 includes a top plate 28a and a bottom plate 28b. In embodiments, the top plate 28a may be a metal material formed in contact with the programming pad 32. The bottom plate 28b may also be a metal material formed over the active device layer 36.

The devices may be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multichip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips may be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either surface interconnections and buried interconnections or both surface interconnections and buried interconnections). In any case the chip is then integrated with other chips, discrete circuit elements, and/or other signal processing devices as part of either (a) an intermediate product, such as a motherboard, or (b) an end product. The end product may be any product that includes integrated circuit chips, ranging from toys and other low-end applications to advanced computer products having a display, a keyboard or other input device, and a central processor.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a programmable element on an active layer of semiconductor material; and
a depletion mode device comprising a dual gate connected to the programmable element.

2. The structure of claim 1, wherein the dual gate comprises a p-doped GaN (pGaN) gate and a depletion mode gate.

3. The structure of claim 2, wherein the pGaN gate is surrounded by the depletion mode gate.

4. The structure of claim 1, wherein the programmable element comprises a gate capacitor.

5. The structure of claim 4, wherein the gate capacitor comprises a pGaN gate structure.

6. The structure of claim 1, further comprising a resistor connected to the programmable element.

7. The structure of claim 6, wherein the resistor comprises a pGaN resistor.

8. The structure of claim 1, wherein the programmable element comprises a top plate which is connected to a programming pad.

9. The structure of claim 8, wherein the top plate comprises a metal material.

10. The structure of claim 1, further comprising an enhancement mode device which is connected to the depletion mode device.

11. The structure of claim 10, wherein the enhancement mode device comprises a transistor.

12. A structure comprising:
at least two depletion mode gate islands; and
at least two gate islands interspersed between the at least two depletion mode gate islands.

13. The structure of claim 12, wherein each of the at least two depletion mode gate islands comprise a depletion mode gate.

14. The structure of claim 13, wherein the depletion mode gate surrounds the at least two gate islands.

15. The structure of claim 13, wherein each of the at least two gate islands comprises a p-doped GaN (pGaN) gate.

16. The structure of claim 15, wherein the depletion mode gate is vertically aligned over the pGaN gate.

17. The structure of claim 15, further comprising a resistor which is connected to the at least two depletion mode gate islands.

18. The structure of claim 15, further comprising a programmable element which is connected to the at least two depletion mode gate islands.

19. The structure of claim 18, wherein the programmable element comprises a gate capacitor.

20. A method comprising:
forming a programmable element on an active layer of a semiconductor material; and
forming a depletion mode device comprising a dual gate in contact with the programmable element.
